(19) United States
(12) Patent Application Publication
(10) Pub. No.: US 2025/0317132 A1
(43) Pub. Date: Oct. 9, 2025

(54) COMPARATOR INCLUDING PLURALITY OF CHANNEL CIRCUITS AND ANALOG-TO-DIGITAL CONVERTER INCLUDING THE SAME

(71) Applicant: SAMSUNG ELECTRONICS CO., LTD., Suwon-si (KR)

(72) Inventors: Jin-Hee Park, Suwon-si (KR); Gil Cho Ahn, Seoul (KR); Hyoung-Jung Kim, Seoul (KR); Myoungbo Kwak, Suwon-si (KR); Jaewoo Park, Suwon-si (KR); Junghwan Choi, Suwon-si (KR)

(73) Assignee: Sogang University Research & Business Development Foundation, Seoul (KR)

(21) Appl. No.: 19/169,286

(22) Filed: Apr. 3, 2025

(30) Foreign Application Priority Data
Apr. 8, 2024 (KR) 10-2024-0047521

(51) Int. Cl. H03K 5/24; H03K 3/037; H03M 1/46

(52) U.S. Cl. CPC H03K 5/249; H03K 3/037; H03M 1/46

(57) ABSTRACT

A comparator includes an input circuit that receives a first input signal and a second input signal, a first sense amplifying circuit that generates a first output signal and a second output signal by amplifying a potential difference between the first input signal and the second input signal, a first clocking transistor circuit that connects the input circuit to the first sense amplifying circuit based on a first clock signal, a second sense amplifying circuit that generates a third output signal and a fourth output signal by amplifying the potential difference between the first input signal and the second input signal, and a second clocking transistor circuit that connects the input circuit to the second sense amplifying circuit based on a second clock signal.

### CROSS-REFERENCE TO RELATED APPLICATION(S)

This application claims priority to Korean Patent Application No. 10-2024-0047521 filed in the Korean Intellectual Property Office on Apr. 8, 2024, the disclosure of which is incorporated by reference herein in its entirety.

### BACKGROUND

Successive Approximation Register (SAR) analog-to-digital converters (ADCs) provide reasonable resolution and conversion time. The SAR analog-to-digital converters implement a binary search algorithm to output a digital code that represents an analog input signal.

The SAR analog-to-digital converters typically include a comparator for comparing an input voltage with a reference voltage. A strongARM latch comparator may be used as the comparator. The strongARM latch comparator may cause kickback noise where level changes at a drain node of an input transistor affect the input signal.

### SUMMARY

In general, in some aspects, the present disclosure is directed toward a comparator in which two comparison circuits operate alternately without increasing input capacitance and kickback noise is reduced, and an analog-to-digital converter including the comparator.

According to some implementations, the present disclosure is directed to a comparator that includes an input circuit that receives a first input signal and a second input signal, a first sense amplifying circuit that generates a first output signal and a second output signal by amplifying a potential difference between the first input signal and the second input signal, a first clocking transistor circuit that connects the input circuit to the first sense amplifying circuit based on a first clock signal, a second sense amplifying circuit that generates a third output signal and a fourth output signal by amplifying the potential difference between the first input signal and the second input signal, and a second clocking transistor circuit that connects the input circuit to the second sense amplifying circuit based on a second clock signal.

According to some implementations, the present disclosure is directed to a comparator that includes an input circuit that receives a first input signal and a second input signal, a plurality of sense amplifying circuits that respectively generates output signals by amplifying a potential difference between the first input signal and the second input signal, based on a first clock signal and a second clock signal which alternately transition to a high level in different time intervals, respectively, and a plurality of clocking transistor circuits that connects the input circuit to each of the plurality of sense amplifying circuits and to receive the first clock signal and the second clock signal.

According to some implementations, the present disclosure is directed to an analog-to-digital converter that includes a DAC circuit that generates a first input signal and a second input signal based on an input voltage, a comparator that compares the input voltage with a reference voltage using the first input signal and the second input signal, and a logic circuit that controls the DAC circuit and generates a digital output signal based on the comparison result of the comparator, and the comparator includes an input circuit that receives the first input signal and the second input signal, a plurality of sense amplifying circuits that respectively generates output signals by amplifying a potential difference between the first input signal and the second input signal, based on a first clock signal and a second clock signal which alternately transition to a high level in different time intervals, respectively, and a plurality of clocking transistor circuits that connects the input circuit and each of the plurality of sense amplifying circuits and receives the first clock signal and the second clock signal.

### BRIEF DESCRIPTION OF THE DRAWINGS

Example implementation will be more clearly understood from the following detailed description, taken in conjunction with the accompanying drawings.

FIG. 1 is a block diagram illustrating an example of an analog-to-digital converter according to some implementations.

FIG. 2 is a block diagram of an example of a comparator according to some implementations.

FIG. 3 is a circuit diagram of an example of a comparator according to some implementations.

FIG. 4 is a block diagram of an example of a comparator according to some implementations.

FIG. 5 is a circuit diagram of an example of a comparator according to some implementations.

FIG. 6 is an example of an operation timing diagram of a comparator according to some implementations.

FIG. 7 is an example of a circuit diagram for describing a comparison operation of a comparator according to some implementations.

FIG. 8 is a circuit diagram for describing an example of a pre-charge operation of a comparator according to some implementations.

FIG. 9 is a block diagram illustrating an example of an analog-to-digital converter according to some implementations.

FIG. 10 is an example of an operation timing diagram of the analog-to-digital converter of FIG. 9 according to some implementations.

FIG. 11 is a circuit diagram of an example of a comparator according to some implementations.

FIGS. 12A and 12B are circuit diagrams of examples of a resistor array and a switch for offset removal according to some implementations.

### DETAILED DESCRIPTION

Hereinafter, example implementations will be described in detail with reference to the accompanying drawings.

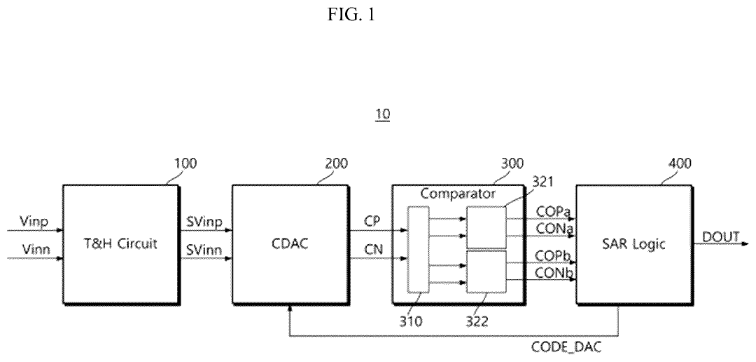

FIG. 1 is a block diagram illustrating an example of an analog-to-digital converter according to some implementations. In FIG. 1, the analog-to-digital converter 10 may be a Successive Approximation Register (SAR) analog-to-digital converter. In some implementations, the analog-to-digital converter 10 may be used as a device for converting an analog signal into a digital signal in electronic devices.

In FIG. 1, the analog-to-digital converter 10 may include a track-and-hold circuit 100, a capacitor-based digital-to-analog converter 200, a comparator 300, and a SAR logic circuit 400.

Input signals Vinp and Vinn may be provided to the track-and-hold circuit 100 through an input line. The input signals Vinp and Vinn may be differential input signals. The input signals Vinp and Vinn may be input voltages. The track-and-hold circuit 100 may conserve differential voltages of the input signals Vinp and Vinn at a specific time. For example, the input signals Vinp and Vinn with differential voltage values at the specific time may be conserved. The track-and-hold circuit 100 may provide conserved differential input signals SVinp and SVinn of the input signals Vinp and Vinn as sampling signals to the capacitor-based digital-to-analog converter 200.

The capacitor-based digital-to-analog converter 200 may generate a first input signal CP and a second input signal CN based on the conserved differential input signals SVinp and SVinn and a reference voltage.

In some implementations, the capacitor-based digital-to-analog converter 200 may be a Capacitive Digital Analog Converter (CDAC). According to some implementations, the capacitor-based digital-to-analog converter 200 may perform a track-and-hold operation and a sampling operation together. In this case, the CDAC-type capacitor-based digital-to-analog converter 200 may perform sampling using any one of top plate sampling, which performs sampling of an input signal from the top plate of the capacitor, and bottom plate sampling, which performs sampling of the input signal from the bottom plate of the capacitor. In some implementations, when the capacitor-based digital-to-analog converter 200 is implemented as the CDAC type, the signal lines that provide the input signals Vinp and Vinn to the digital-to-analog converter 200 may each be electrically coupled to a capacitor array. In this case, potentials of the input signals Vinp and Vinn may be used to pre-charge a plurality of capacitors of the capacitor array. The unit capacitor array topology of the capacitor array may be implemented in various ways.

The capacitor-based digital-to-analog converter 200 may provide the first input signal CP and the second input signal CN each converted from the input signals Vinp and Vinn to the comparator 300. In some implementations, the first input signal CP and the second input signal CN may be signals obtained by adding or subtracting a certain ratio of the reference voltage from the values obtained by adding or subtracting the differential voltages of the input signal Vinp and Vinn from the common mode voltage.

The comparator 300 may use the first input signal CP and the second input signal CN to determine whether the differential voltages of the input signals Vinp and Vinn are greater or less than the reference value. The comparator 300 may be called a determination latch.

After each determination performed by the comparator 300, the determination results may be stored in a memory of the SAR logic circuit 400. The memory of the SAR logic circuit 400 may be a shift register. The SAR logic circuit 400 may provide the capacitor-based digital-to-analog converter 200 with a control signal for changing the reference value of the capacitor-based digital-to-analog converter 200. For example, the SAR logic circuit 400 may generate a control signal CODE_DAC for selecting capacitors from among the capacitor array of the capacitor-based digital-to-analog converter 200, and may provide the generated control signal CODE_DAC to the capacitor-based digital-to-analog converter 200. The SAR logic circuit 400 may output the determined result as binary bit data DOUT.

According to some implementations, the comparator 300 may receive the first input signal CP and the second input signal CN through one input circuit 310. The input circuit 310 may be a differential input pair. The input circuit 310 may be connected to a plurality of sense amplifying circuits included in channels 321 and 322 through a clocking transistor circuit. In some implementations, the sense amplifying circuit may include an inverter latch. The comparator 300 may alternately activate each of the channels 321 and 322 including a plurality of sense amplifying circuits. The activated channel may generate an output signal based on the first input signal CP and the second input signal CN. The sense amplifying circuit of the activated channel may generate output signals by amplifying a potential difference between the first input signal CP and the second input signal CN. Accordingly, the plurality of channels 321 and 322 may share the one input circuit 310.

For example, the input circuit 310 may activate the first channel 321 at a first time, and the sense amplifying circuit of the first channel 321 may generate output signals COPa and CONa by amplifying a potential difference between the first input signal CP and the second input signal CN. The input circuit 310 may activate the second channel 322 at a second time different from the first time, and the sense amplifying circuit of the second channel 322 may activate output signals COPb and CONb by amplifying a potential difference between the first input signal CP and the second input signal CN, which are received at the second time.

Accordingly, the input capacitance of the comparator 300 may not increase even though there are a plurality of channels. For example, the comparator 300 may not increase the input capacitance by alternately driving inverter latches of the plurality of channels using the input circuit 310, which is one differential input pair.

Additionally, the comparator 300 may reduce the influence of kickback noise caused by a gate-source parasitic capacitor of the transistor included in the differential input pair by configuring the differential input pair in a pseudo-differential method. Accordingly, the analog-to-digital converter 10 may perform accurate analog-to-digital conversion.

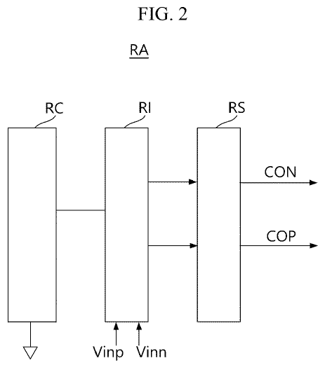

FIG. 2 is a block diagram of an example of a comparator RA according to some implementations. The comparator RA may include a clocking transistor circuit RC, an input circuit RI, and a sense amplifying circuit RS.

The clocking transistor circuit RC of the comparator RA may include a clocking transistor. The clocking transistor may receive a clock signal through its gate node and may be connected to a ground electrode. Based on the clock signal, the sense amplifying circuit RS may be activated or deactivated.

The input circuit RI may include a plurality of input transistors and may receive a plurality of input signals Vinp and Vinn through a gate node of each of the plurality of input transistors. The sense amplifying circuit RS may generate output signals CON and COP by amplifying a potential difference between the input signals Vinp and Vinn when the clocking transistor circuit RC is turned on. Unlike the comparator 300 in FIG. 1, in the comparator RA, the clocking transistor circuit RC may be connected to a ground electrode, and the input circuit RI may be directly connected to the sense amplifying circuit RS. Accordingly, when the comparator RA according to the comparison technology includes a plurality of sense amplifying circuits, an input circuit connected to each sense amplifying circuit is individually required. For this reason, when the comparator RA includes a plurality of sense amplifying circuits, an input capacitance increases.

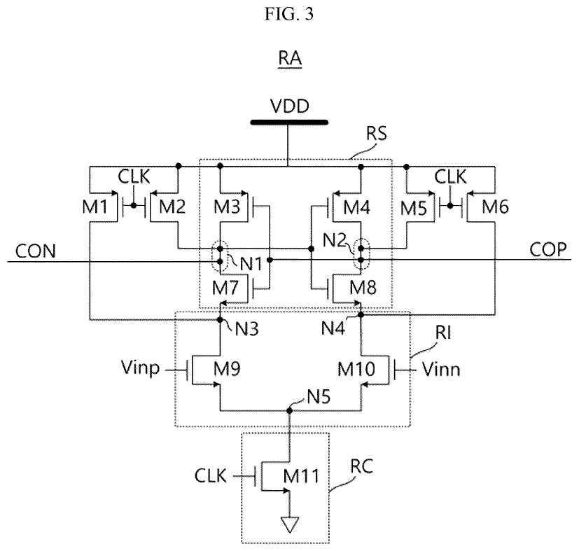

FIG. 3 is a circuit diagram of an example of a comparator according to some implementations. The comparator RA in FIG. 3 may correspond to the comparator RA in FIG. 2. The comparator RA may include the clocking transistor circuit RC, the input circuit RI, and the sense amplifying circuit RS.

The sense amplifying circuit RS includes a plurality of complementary metal-oxide semiconductor (CMOS) circuits that are cross coupled to each other. For example, among the plurality of CMOS circuits, gate nodes of a PMOS transistor M3 and an NMOS transistor M7 of a first CMOS circuit are connected to a second node N2, which is an output node of a second CMOS circuit, and gate nodes of a PMOS transistor M4 and a NMOS transistor M8 of the second CMOS circuit are connected to a first node N1, which is an output node of the first CMOS circuit.

The comparator RA may include a plurality of pre-charge circuits. Among the plurality of pre-charge circuits, a first pre-charge circuit includes transistors M1 and M2 that receive a clock signal CLK to their gate nodes, and a second pre-charge circuit includes transistors M5 and M6 that receive the clock signal CLK to their gate nodes.

The input circuit RI includes input transistors M9 and M10 that receive the plurality of input signals Vinp and Vinn to their gate nodes, respectively. The input circuit RI of the comparator RA connects the sense amplifying circuit RS to the clocking transistor circuit RC. For example, the input circuit RI is connected to the first CMOS circuit of the sense amplifying circuit RS through a third node N3, and is connected to the second CMOS circuit of the sense amplifying circuit RS through a fourth node N4. The input circuit RI is connected to the clocking transistor circuit RC through a fifth node N5.

The clocking transistor circuit RC includes a transistor M11 that receives the clock signal CLK to its gate node, a source node of the transistor M11 is connected to the ground electrode, and a drain node of the transistor M11 is connected to the input circuit RI.

The input circuit RI of the comparator RA is located between the sense amplifying circuit RS and the clocking transistor circuit RC, so that when a plurality of sense amplifying circuits RS are required, each sense amplifying circuit RS requires the corresponding input circuit RI. Accordingly, when the comparator RA according to the comparison technology requires the plurality of sense amplifying circuits RS, the number of input circuits RI increases in proportion to the number of sense amplifying circuits RS. As a result, the number of input transistors M9 and M10 increases in proportion to the number of input circuits RI. Additionally, the capacitance caused by the wiring of the signal lines connected to the gate nodes of the input transistors M9 and M10 increases in proportion to the number of input circuits RI. Accordingly, when multiple comparators RA according to comparison technology are used, the input capacitance increases. As a result, when an input buffer is included in the analog-to-digital converter using the comparator RA, the size and driving power of the input buffer may increase. Additionally, the settling time of the digital-to-analog converter that provides a reference voltage (or comparison voltage) to the comparator RA may increase. Sampling bandwidth may also be reduced.

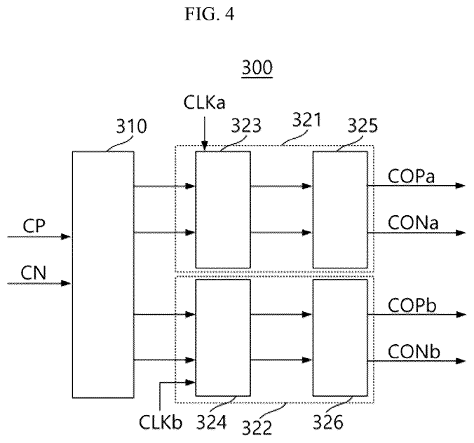

FIG. 4 is a block diagram of an example of a comparator according to some implementations. The comparator 300 of FIG. 4 may correspond to the comparator 300 described with reference to FIG. 1.

The comparator 300 may include the one input circuit 310 and the plurality of channels 321 and 322. Each of the plurality of channels 321 and 322 may include clocking transistor circuits 323 and 324 and sense amplifying circuits 325 and 326. For example, the first channel 321 may include the first clocking transistor circuit 323 and the first sense amplifying circuit 325, and the second channel 322 may include the second clocking transistor circuit 324 and the second sense amplifying circuit 326.

Unlike the comparator RA described with reference to FIG. 3, the comparator 300 includes the plurality of channels 321 and 322 each including the clocking transistor circuits 323 and 324 and the sense amplifying circuits 325 and 326, and the plurality of channels 321 and 322 share the one input circuit 310. Different clock signals CLKa and CLKb are provided to each of the plurality of channels 321 and 322, and based on the clock signals CLKa and CLKb supplied to the channels 321 and 322, any one of the plurality of channels 321 and 322 may be activated alternately over time. In some implementations, the clock signals CLKa and CLKb may be provided from the SAR logic circuit 400.

The activated channel may generate output signals based on the first input signal CP and the second input signal CN. For example, the first channel 321 activated at a first time may amplify a potential difference between the first input signal CP and the second input signal CN at the first time to generate the output signals COPa and CONa. The second channel 322 activated at a second time may generate the output signals COPb and CONb by amplifying the potential difference between the first input signal CP and the second input signal CN at the second time.

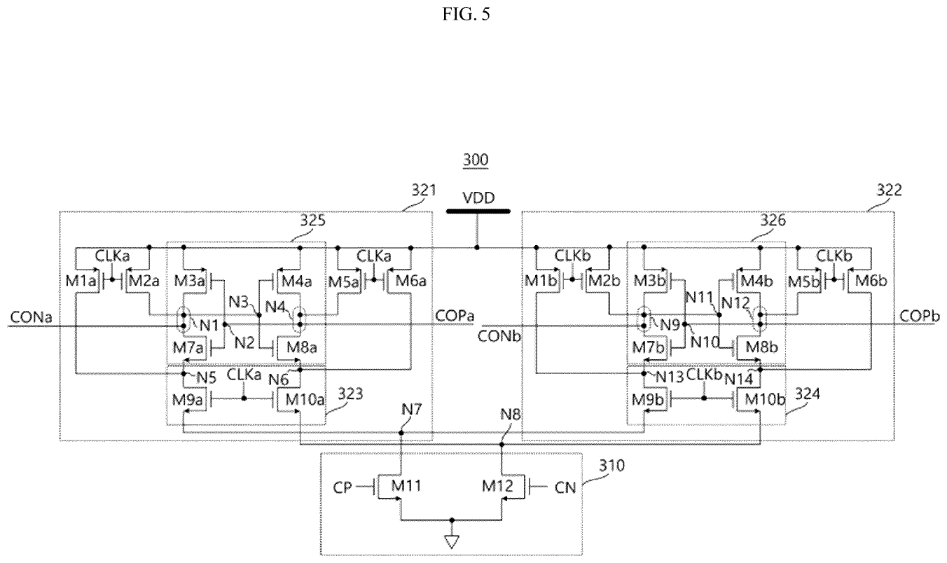

FIG. 5 is a circuit diagram of an example of a comparator according to some implementations. The comparator 300 described with reference to FIG. 5 may correspond to the comparator 300 of FIGS. 1 and 4.

In FIG. 5, the comparator 300 may include the input circuit 310, the first channel 321, and the second channel 322. The first channel 321 and the second channel 322 may include the clocking transistor circuit and the sense amplifying circuit, respectively. For example, the first channel 321 may include the first clocking transistor circuit 323 and the first sense amplifying circuit 325, and the second channel 322 may include the second clocking transistor circuit 324 and the second sense amplifying circuit 326.

The first channel 321 and the second channel 322 may be connected to the input transistors M11 and M12 of the input circuit 310 through the same nodes N7 and N8. The first channel 321 and the second channel 322 may generate output signals by amplifying the potential difference between the first input signal CP and the second input signal CN that are provided through the one input circuit 310, based on the clock signals CLKa and CLKb. The output signals of the first channel 321 and the second channel 322 may be generated based on differential input voltage values sampled at different times. For example, the first channel 321 may generate the first output signal COPa and the second output signal CONa based on the first input signal CP and the second input signal CN provided through the input circuit 310 at the first time. The second channel 322 may generate the third output signal COPb and the fourth output signal CONb based on the first input signal CP and the second input signal CN provided through the input circuit 310 at the second time.

The first channel 321 and the second channel 322 may have the same circuit configuration. Below, the configuration of the first channel 321 will be mainly described, but the second channel 322 may also have the same configuration as the first channel 321. For example, the first sense amplifying circuit 325 of the first channel 321 may have the same configuration as the second sense amplifying circuit 326 of the second channel 322. The first clocking transistor circuit 323 of the first channel 321 may have the same configuration as the second clocking transistor circuit 324 of the second channel 322.

The first sense amplifying circuit 325 may include a plurality of CMOS circuits. Among the plurality of CMOS circuits, the first CMOS circuit may include a PMOS transistor (p-type

Metal Oxide Semiconductor Field Effect transistor) M3a and an NMOS transistor M7a, which are connected in series with each other. A gate node of the PMOS transistor M3a of the first CMOS circuit is connected to a gate node of the NMOS transistor M7a. Among the plurality of CMOS circuits, the second CMOS circuit may include a PMOS transistor M4a and an NMOS transistor M8a, which are connected in series with each other. A gate node of the PMOS transistor M4a of the second CMOS circuit is connected to a gate node of the NMOS transistor M8a. The first CMOS circuit and the second CMOS circuit may be cross-coupled with each other. In detail, the gate nodes of the PMOS transistor M3a and the NMOS transistor M7a of the first CMOS circuit may be connected to the fourth node N4, which is the output node of the second CMOS circuit, through the second node N2, and the gate nodes of the PMOS transistor M4a and the NMOS transistor M8a of the second CMOS circuit may be connected to the first node N1, which is the output node of the first CMOS circuit, through the third node N3.

The comparator 300 may include a plurality of pre-charge circuits. Among the plurality of pre-charge circuits, a first pre-charge circuit may include transistors Mla and M2a that receive the clock signal CLK to their gate nodes, and a second pre-charge circuit may include transistors M5a and M6a that receive the clock signal CLK to their gate nodes.

Source nodes of the transistors Mla, M2a, M5a, and M6a of the first pre-charge circuit and the second pre-charge circuit may be connected to the power supply voltage. A drain node of the transistor M1a of the first pre-charge circuit may be connected to a source node of the pull-down transistor M7a of the first CMOS circuit through the fifth node N5. A drain node of the transistor M2a of the first pre-charge circuit may be connected to the first node N1, which is the output node of the first CMOS circuit. A drain node of the transistor M6a of the second pre-charge circuit may be connected to a source node of the pull-down transistor M8a of the second CMOS circuit through the sixth node N6. A drain node of the transistor M5a of the second pre-charge circuit may be connected to the fourth node N4, which is the output node of the second CMOS circuit.

The first clocking transistor circuit 323 may include transistors M9a and M10a that receive a clock signal CLKa to their gate nodes. A drain node of the first clocking transistor M9a and a drain node of the second clocking transistor M10a of the first clocking transistor circuit 323 may each be connected to the first sense amplifying circuit 325. For example, the drain node of the first clocking transistor M9a may be connected to the source node of the pull-down transistor M7a of the first CMOS circuit, and the drain node of the second clocking transistor M10a may be connected to the source node of the pull-down transistor M8a of the second CMOS circuit.

The source node of the first clocking transistor M9a and the source node of the second clocking transistor M10a of the first clocking transistor circuit 323 may each be connected to the input circuit 310. For example, the source node of the first clocking transistor M9a may be connected to the drain node of the first input transistor M11 of the input circuit 310, and the source node of the second clocking transistor M10a may be connected to the drain node of the second input transistor M12 of the input circuit 310.

The nodes N7 and N8 where the first clocking transistor circuit 323 of the first channel 321 is connected to the input circuit 310 are connected to the second clocking transistor circuit 324 of the second channel 322. For example, the nodes N7 and N8 may be connected to a source node of a third clocking transistor M9b and a source node of a fourth clocking transistor M10b of the second clocking transistor circuit 324, respectively. Accordingly, the first channel 321 and the second channel 322 may be connected to the same input circuit 310. The first channel 321 and the second channel 322 may generate output signals by amplifying the potential difference between the input signals CP and CN at different times provided to the same input circuit 310.

The input circuit 310 may include the first input transistor M11 that receives the first input signal CP to its gate node, and the second input transistor M12 that receives the second input signal CN to its gate node. The drain node of the first input transistor M11 may be connected to the source node of the first clocking transistor M9a of the first clocking transistor circuit 323 through the node N7. The drain node of the second input transistor M12 may be connected to the source node of the second clocking transistor M10a of the first clocking transistor circuit 323 through the node N8. Additionally, the first input transistor M11 may be connected to the third clocking transistor M9b of the second clocking transistor circuit 324 through the node N7, and the second input transistor M12 may be connected to the fourth clocking transistor M10b of the second clocking transistor circuit 324 through the node N8. The source nodes of the first input transistor M11 and the second input transistor M12 of the input circuit 310 may be connected to the ground electrode. Accordingly, the input transistors M11 and M12 are located between the clocking transistor of the activated channel and the ground electrode, so that kickback noise may be reduced. Additionally, since a plurality of channels are activated alternately, a channel that is not activated may be pre-charged for a sufficient period of time while activated channel is operating.

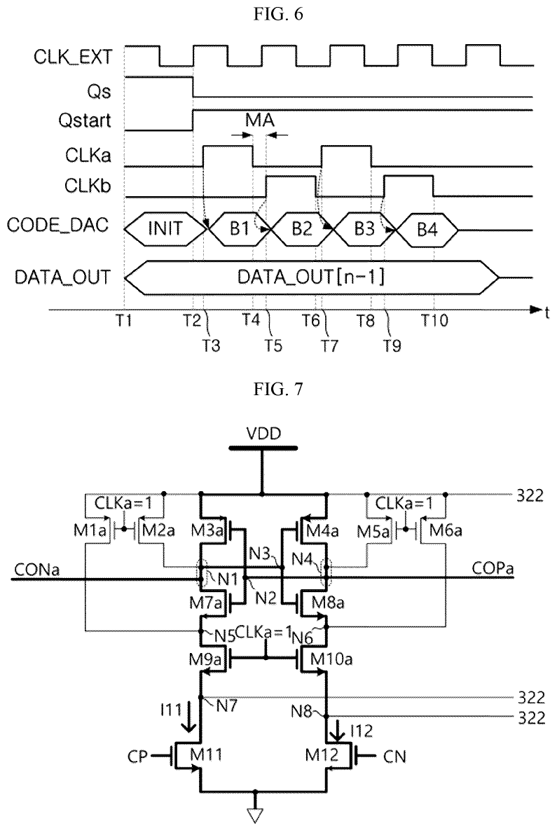

FIG. 6 is an example of an operation timing diagram of the analog-to-digital converter 10 of FIG. 1 according to some implementations. The operation timing described with reference to FIG. 6 may correspond to the operation timing of the analog-to-digital converter 10 of FIG. 1 including the comparator 300 of FIG. 5. The operation of the analog-to-digital converter 10 will be described with reference to FIGS. 1, 5, and 6. The operation of the analog-to-digital converter 10 of FIG. 6 will be described on the premise of generating 4 binary bit data DOUT.

The operation timing diagram of FIG. 6 is assumed that the track-and-hold circuit 100 operates based on a sampling clock signal Qs, and the first clock signal CLKa and the second clock signal CLKb are provided to the comparator 300 based on a start clock signal Qstart. The sampling clock signal Qs and the start clock signal Qstart may be generated based on an external clock signal CLK_EXT. For example, a clock signal generator (not illustrated) that receives the external clock signal CLK_EXT may generate the sampling clock signal Qs and the start clock signal Qstart based on the external clock signal CLK_EXT. An asynchronous logic circuit (not illustrated) that receives the start clock signal Qstart may start clocking of the first clock signal CLKa based on the start clock signal Qstart. Thereafter, the first channel 321 may compare the input signals CP and CN at the first time based on a first period of the first clock signal CLKa and may generate the output signals COPa and CONa. Based on the output signals COPa and CONa of the first channel 321, the first clock signal CLKa may transition to a first (low) level, and the second clock signal CLKb may transition to a second (high) level greater than the first level. The second channel 322 may compare the input signals CP and CN at the second time based on the second clock signal CLKb and may generate the output signals COPb and CONb. Afterwards, the same process may be repeated.

In FIG. 6, phases of the first clock signal CLKa and the second clock signal CLKb are different from each other. In detail, while one of the first clock signal CLKa and the second clock signal CLKb is at a high level, the other clock signal maintains a low level. Accordingly, the first channel 321 receiving the first clock signal CLKa and the second channel 322 receiving the second clock signal CLKb may alternately perform a comparison operation.

At time T1, the track-and-hold circuit 100 may track the input signals Vinp and Vinn in response to the sampling clock signal Qs having a high level.

The SAR logic circuit 400 may provide an initialization signal INIT such that the capacitor-based digital-to-analog converter 200 generates the reference voltage.

At time T2, the sampling clock signal Qs may transition to a low level, and the start clock signal Qstart may transition to a high level.

At time T3, the first clock signal CLKa may transition to a high level. In response to the first clock signal CLKa of the high level, the SAR logic circuit 400 of FIG. 1 may provide a bit control signal B1 for generating a reference voltage for a first comparison cycle of the first channel 321 to the capacitor based digital-to-analog converter 200. The first clocking transistor circuit 323 and the first sense amplifying circuit 325 of the first channel 321 of the comparator 300 of FIG. 5 may be activated in response to the first clock signal CLKa of the high level. The first sense amplifying circuit 325 may generate the comparison result as the output signals COPa and CONa.

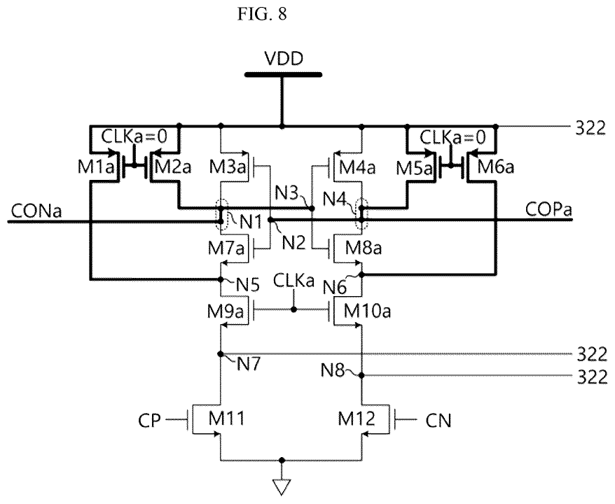

FIG. 7 illustrates an example of an operation in which the first channel 321 of the comparator 300 of FIG. 5 is activated and a comparison operation is performed according to some implementations. In FIG. 7, the first pre-charge circuit and the second pre-charge circuit do not operate depending on the first clock signal CLKa of the high level. For example, the first clock signal CLKa of the high-level is provided to the gate nodes of the PMOS transistors M1a and M2a of the first pre-charge circuit and the PMOS transistors M5a and Moa of the second pre-charge circuit, and then the PMOS transistors Mla, M2a, M5a, and M6a are turned off.

When the first clock signal CLKa transitions to the high level, the transistors M1a, M2a, M5a, and M6a of the first pre-charge circuit and the second pre-charge circuit are turned off, but the output nodes N1 and N4 are not started discharging, so the output nodes N1 and N4 are still in a pre-charge state with the power supply voltage VDD.

The first clocking transistor M9a and the second clocking transistor M10a are turned on by the first clock signal CLKa of the high level, and the first input transistor M11 and the second input transistor M12 are turned on by the first input signal CP and the second input signal CN.

In some implementations, threshold voltages of the gate nodes of the first input transistor M11 and the second input transistor M12 may be less than the first input signal CP and the second input signal CN, respectively. The potentials of the seventh node N7 and the eighth node N8 may be maintained equal to the ground potential. Accordingly, the memory effect may not occur in the seventh node N7 and the eighth node N8 between the input circuit 310 of FIG. 5 and the clocking transistor circuits 323 and 324 of FIG. 5.

While the first clock signal CLKa maintains the high level, the turned-on first and second input transistors M11 and M12 drains currents I11 and 112, respectively. The output nodes Nl and N4 start discharging depending on the drained currents I11 and 112.

The magnitudes of the currents I11 and 112 flowing through each of the first input transistor M11 and the second input transistor M12 may be different depending on the difference in level between the first input signal CP and the second input signal CN. As a result, the discharging speeds of the output nodes N1 and N4 may be different. Due to the different discharging speeds of the output nodes N1 and N4 and the first sense amplifying circuit 325 composed of an inverter latch, the faster discharged output node among the output nodes N1 and N4 may maintain a value of “0”, and other output node may maintain a value of “1”.

At time T4, the first clock signal CLKa may transition to a low level. The first pre-charge circuit and the second pre-charge circuit of the first channel 321 of the comparator 300 of FIG. 5 may pre-charge the first channel 321.

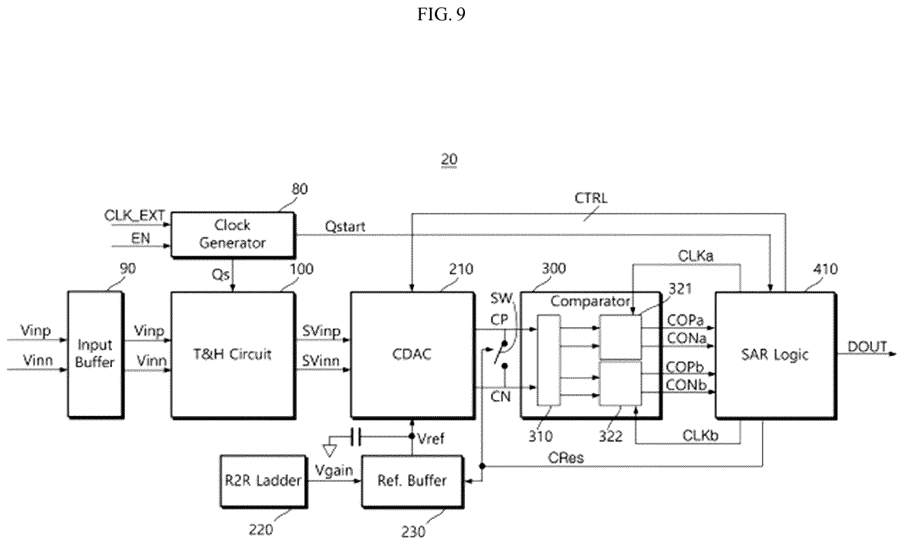

FIG. 8 illustrates an example of an operation in which the first channel 321 of the comparator 300 of FIG. 5 performs the pre-charge according to some implementations. In FIG. 8, in response to the first clock signal CLKa of a low level, the PMOS transistors M1a and M2a of the first pre-charge circuit and the PMOS transistors M5a and M6a of the second pre-charge circuit are turned on. By turning on the transistors M1a, M2a, M5a, and M6a of the first pre-charge circuit and the second pre-charge circuit, the power supply voltage is applied to the output nodes N1 and N4, the input nodes N2 and N3, and the nodes N5 and N6. By pre-charging with the power supply voltage, the potential differences between the output nodes N1 and N4, between the input nodes N2 and N3, and between the nodes N5 and N6, which are occurred in the previous time are reset.

At time T5, the second clock signal CLKb transitions to a high level. In an embodiment, the second clock signal CLKb may transition to the high level at time T5, which is after a predetermined time MA is elapsed from time T4 when the first clock signal CLKa transitions to the low level. In detail, the second channel 322 may perform a comparison operation after the reset of the first channel 321 is completed. Likewise, in another time period, the first channel 321 may perform the comparison operation after the reset of the second channel 322 is completed. Similar to the comparison operation of the first channel 321 described at time T3, at time T5, the second channel 322 performs the comparison operation.

At time T6, the second clock signal CLKb transitions to a low level. Similar to the pre-charge operation of the first channel 321 described at time T4, the second channel 322 performs a pre-charge operation.

At times T7 and T8, the first channel 321 performs the comparison operation and the pre-charge operation again, respectively, and at times T9 and T10, the second channel 322 performs the comparison operation and the pre-charge operation again, respectively. The binary bit data DOUT converted by the operation of the first channel 321 and the second channel 322 between time T1 and time T10 may be output while a comparison operation of the subsequent input signal is performed. Accordingly, bit data DATA_OUT[n−1] may be output between time T1 and time T10 by comparing the previous input signals.

In FIG. 6, there is a specific time interval MA between the time when the first clock signal CLKa transitions to a low level and the time when the second clock signal CLKb transitions to a high level. Likewise, there is a specific time interval between the time when the second clock signal CLKb transitions to the low level and the time when the first clock signal CLKa transitions to the high level. Additionally, the periods during which the first clock signal CLKa and the second clock signal CLKb maintain the high level and the periods during which the first clock signal CLKa and the second clock signal CLKb maintain the low level are different from each other. For example, the periods during which the first clock signal CLKa and the second clock signal CLKb maintain a low level may be slightly longer than the periods during which the first clock signal CLKa and the second clock signal CLKb maintain a high level. Accordingly, the pre-charge operation of each of channels 321 and 322 may be performed more smoothly.

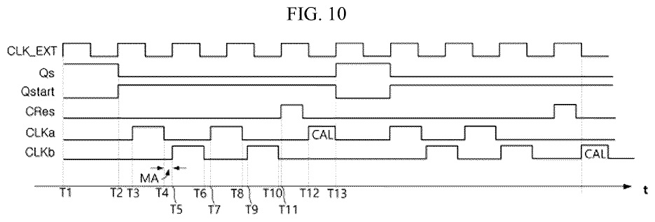

FIG. 9 is a block diagram illustrating an example of an analog-to-digital converter according to some implementations. An analog-to-digital converter 20 described with reference to FIG. 9 may include the comparator 300 of FIG. 5. Additional descriptions of parts similar to the analog-to-digital converter 10 described with reference to FIG. 1 will be omitted to avoid redundancy. The analog-to-digital converter 20 will be described with reference to FIGS. 5 and 9.

The analog-to-digital converter 20 may include a clock generator 80, an input buffer 90, the track-and-hold circuit 100, a capacitor-based digital-to-analog converter (CDAC) 210, the comparator 300, and a SAR logic circuit 410.

The clock generator 80 may receive the external clock signal CLK_EXT and an enable signal EN. Based on the enable signal EN, the clock generator 80 may provide the sampling clock signal Qs to the track-and-hold circuit 100 and may provide the start clock signal Qstart to the SAR logic circuit 410. For example, the clock generator 80 may provide the sampling clock signal Qs of a high level to the track-and-hold circuit 100 in response to the enable signal EN of the high level. After a preset time, the clock generator 80 may transition the sampling clock signal Qs from the high level to the low level and may provide the start clock signal Qstart of the high level to the SAR logic circuit 410.

The input signals Vinp and Vinn may be input to the input buffer 90 through input lines. The input buffer 90 may provide buffered input signals Vinp and Vinn to the track-and-hold circuit 100.

The track-and-hold circuit 100 may conserve differential voltages of the input signals Vinp and Vinn at a specific time. The track-and-hold circuit 100 may provide the conserved differential input signals SVinp and SVinn of the input signals Vinp and Vinn as sampling signals to the capacitor-based digital-to-analog converter 210. The track-and-hold circuit 100 may operate based on the first start signal Qs. For example, the track-and-hold circuit 100 may conserve the differential voltages of the input signals Vinp and Vinn in response to the first start signal Qs of a high level.

The capacitor-based digital-to-analog converter 210 may generate the first input signal CP and the second input signal CN based on a control signal CTRL provided from the SAR logic circuit 410, the conserved input signals SVinp and SVinn, and a reference voltage Vref. The capacitor-based digital-to-analog converter 210 may include a capacitor array composed of a plurality of capacitors. There is a plurality of capacitor arrays, and each capacitor array may be electrically coupled to signal lines that provide the conserved input signals SVinp and SVinn.

A reference buffer 230 is controlled by a gain voltage Vgain provided from an R2R ladder 220 and may control a gain of the analog-to-digital converter 20.

The capacitor-based digital-to-analog converter 210 may provide the first input signal CP and the second input signal CN each converted from the input signals Vinp and Vinn to the comparator 300.

The comparator 300 may include the plurality of channels 321 and 322 sharing one input circuit 310. The comparator 300 may determine whether the differential voltages of the input signals Vinp and Vinn is greater or less than the reference value using the first input signal CP and the second input signal CN, using the plurality of channels 321 and 322.

After each determination performed by comparator 300, the determination results may be stored in a memory of the SAR logic circuit 400. The SAR logic circuit 410 may output the determined result as binary bit data DOUT.

The SAR logic circuit 410 may operate based on the second start signal Qstart. For example, the SAR logic circuit 410 may provide the control signal CTRL to the CDAC 210 in response to the second start signal Qstart of a high level and may provide the clock signals CLKa and CLKb and a reset signal CRes to the comparator 300.

The plurality of channels 321 and 322 of the comparator 300 may include the clocking transistor circuits 323 and 324 and the sense amplifying circuits 325 and 326 of FIG. 5. The clocking transistor circuits 323 and 324 may receive the first clock signal CLKa and the second clock signal CLKb from the SAR logic circuit 410, respectively. The plurality of channels 321 and 322 may be activated alternately based on the first clock signal CLKa and the second clock signal CLKb. The signal lines providing the first input signal CP and the second input signal CN to the input circuit 310 may be reset by the reset signal CRes provided from the SAR logic circuit 410. For example, the signal lines providing the first input signal CP and the second input signal CN to the input circuit 310 may be connected to each other at a high level of the reset signal CRes and may set to a common mode. In an embodiment, a switch SW may be closed immediately after a least significant bit (LSB) determination of the binary bit data DOUT begins.

In FIG. 9, each of the signal lines providing the first input signal CP and the second input signal CN is connected to one input circuit 310. For example, as described with reference to FIG. 5, the first sense amplifying circuit 325 and the second sense amplifying circuit 326 are alternately driven using the input transistors M11 and M12 of the one input circuit 310. As a result, despite using the plurality of sense amplifying circuits 325 and 326, the capacitance due to the input transistors M11 and M12 and the wiring of the signal lines connected to the input transistors M11 and M12 does not increase. As a result, despite driving the plurality of sense amplifying circuits 325 and 326 alternately, the power consumed in the input buffer 90 and/or the area of the input buffer 90 do not increase. In addition, the setting time of the capacitor-based digital-to-analog converter 210 may be reduced. Additionally, sampling bandwidth may be increased.

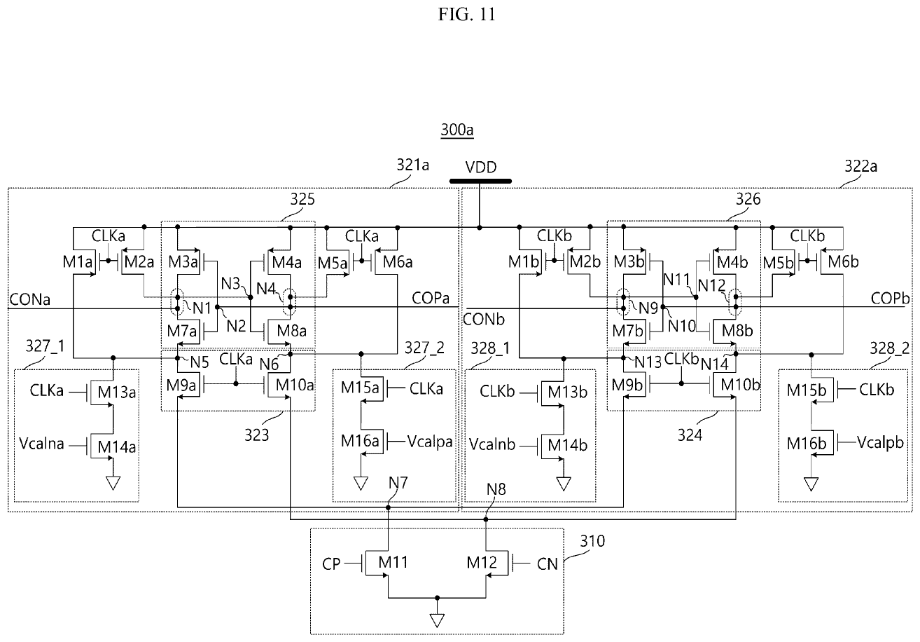

FIG. 10 is an example of an operation timing diagram of the analog-to-digital converter 20 of FIG. 9 according to some implementations. The operation of the analog-to-digital converter 20 will be described with reference to FIGS. 9 and 10. The operation of the analog-to-digital converter 20 of FIG. 10 will be described on the premise of generating 4 binary bit data DOUT. The operation of the analog-to-digital converter 20 will be described focusing on differences from the operation of the analog-to-digital converter 10 described in FIG. 6.

Unlike the analog-to-digital converter 10 described in FIG. 6, the analog-to-digital converter 20 may output the binary bit data DOUT and then may perform calibration CAL of the first channel 321 and the second channel 322, alternately.

For example, a calibration voltage or a voltage complementary to the calibration voltage may be applied to the gate node of any one of the input transistors of the channel being calibrated. The calibration voltage may be based on the output signal of the channel being calibrated. Depending on the embodiment, the analog-to-digital converter 20 may not perform the calibration CAL.

At time T1, the clock generator 80 may provide the sampling clock signal Qs of a high level to the track-and-hold circuit 100 based on the enable signal EN, and may provide the start clock signal Qstart of a low level to the SAR logic circuit 410. The track-and-hold circuit 100 may conserve the input signals Vinp and Vinn in response to the sampling clock signal Qs of the high level.

At time T2, the SAR logic circuit 410 may receive the start clock signal Qstart of a high level.

At time T3, the SAR logic circuit 410 provides clock signals CLKa and CLKb to the channels 321 and 322, respectively, from time T3 in response to the enable signal EN transitioned to the high level.

In FIG. 10, the phases of the first clock signal CLKa and the second clock signal CLKb provided to the comparator 300 are different from each other. In detail, while one of the first clock signal CLKa and the second clock signal CLKb is at a high level, the other clock signal maintains a low level. Accordingly, the first channel 321 receiving the first clock signal CLKa and the second channel 322 receiving the second clock signal CLKb may alternately perform a comparison operation.

As described with respect to FIG. 6, the first channel 321 performs a comparison operation in response to the first clock signal CLKa of the high level for a specific period of time from time T3 and time T7. The second channel 322 performs a comparison operation in response to the second clock signal CLKb of the high level from time T5 and time T9. The first channel 321 performs a pre-charge operation for a specific period of time from time T4 and time T8. The second channel 322 performs a pre-charge operation for a specific period of time from time T6 and time T10. At time T11, the reset signal CRes of the high level may be provided to the switch SW that connects between the input lines providing the input signals CP and CN to each other. The switch SW is closed by the reset signal CRes of the high level, and the input lines providing the input signals CP and CN may be reset. At time T12, the calibration CAL with respect to the first channel 321 may be performed.

From time T13, tracking of the track-and-hold circuit 100 may be performed. Additionally, the comparison operation and pre-charge operation of the first channel 321 and the second channel 322 are repeated. Subsequent calibration may be performed with respect to the second channel 322.

In FIG. 10, there is the specific time interval MA between the time when the first clock signal CLKa transitions to a low level and the time when the second clock signal CLKb transitions to a high level. Likewise, there also is a specific time interval between the time when the second clock signal CLKb transitions to the low level and the time when the first clock signal CLKa transitions to the high level. Accordingly, one channel may perform the comparison operation after the reset of the other channel is completed.

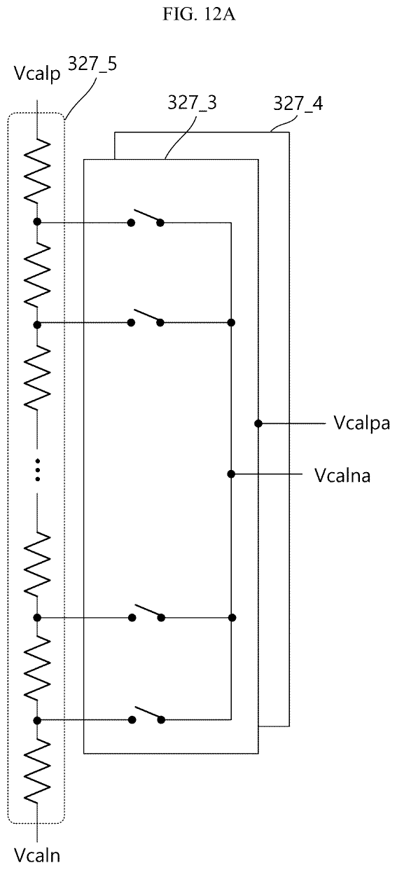

FIG. 11 is an example of a circuit diagram of a comparator 300a according to some implementations. Additional descriptions of parts similar to the comparator 300 described with reference to FIG. 5 will be omitted to avoid redundancy. The comparator 300a will be described with reference to FIG. 11. The comparator 300a described with reference to FIG. 11 may be used in the analog-to-digital converters 10 and 20 of FIGS. 1, 4, and 10.

In FIG. 11, the comparator 300a may include the input circuit 310, a first channel 321a, and a second channel 322a. The first channel 321a and the second channel 322a may include a clocking transistor circuit and a sense amplifying circuit, respectively. For example, the first channel 321a may include the first clocking transistor circuit 323 and the first sense amplifying circuit 325, and the second channel 322a may include the second clocking transistor circuit 324 and the second sense amplifying circuit 326.

Unlike the comparator 300 described with reference to FIG. 5, the first channel 321a of the comparator 300a according to the embodiment of the present disclosure may include a first offset bias circuit 327_1 connected to the fifth node N5 and a second offset bias circuit 327_2 connected to the sixth node N6. Additionally, the second channel 322a may include a third offset bias circuit 328_1 connected to a thirteenth node N13 and a fourth offset bias circuit 328_2 connected to a fourteenth node N14. The first offset bias circuit 327_1, the second offset bias circuit 327_2, the third offset bias circuit 328_1, and the fourth offset bias circuit 328_2 may have the same configuration to each other. Below, the first offset bias circuit 327_1 will be described as an example.

The first offset bias circuit 327_1 may include a first offset transistor M13a including a gate node to which the first clock signal CLKa is applied, a drain node connected to the fifth node N5, and a source node connected to a drain node of a first bias transistor M14a. The first offset bias circuit 327_1 may include the first bias transistor M14a connected in series with the first offset transistor M13a.

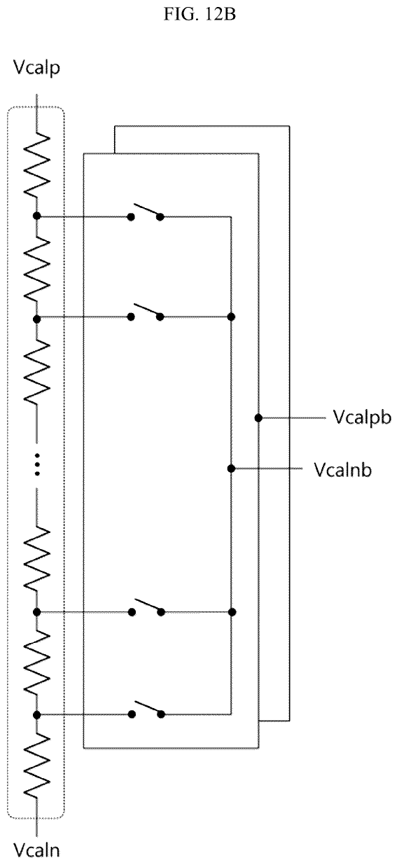

The first bias transistor M14a may receive a calibration voltage Vcalna to its gate node. For example, the calibration voltage Vcalna may be output from an offset cancellation circuit of FIG. 12A. The offset cancellation circuit may output a voltage between a first calibration voltage Vcalp and a second calibration voltage Vcaln by selecting some of the plurality of switches of a switch circuit 327_3. Likewise, a calibration voltage Vcalpa that is provided to a gate node of a second bias transistor M16a of the second offset bias circuit 327_2 of the first channel 321 may be a voltage output based on a switch circuit 327_4. Calibration voltages Vcalpb and Vcalnb provided to the second channel 322 may also be generated in the same way as described above through an offset cancellation circuit of FIG. 12B.

The calibration voltages may be determined to cancel an offset that occurs depending on the characteristics of the transistors of the first channel 321a and the second channel 322a. For example, the calibration voltage Vcalna provided to the first bias transistor M14a and the calibration voltage Vcalpa provided to the second bias transistor M16a may be determined based on offset currents of the fifth node N5 and the sixth node N6.

The input signals CP and CN may be accurately converted into analog-to-digital by using the offset bias circuit and the offset cancellation circuit described with reference to FIGS. 11 and 12.

According to some implementations, the comparator and the analog-to-digital converter including the comparator may perform the accurate analog-to-digital conversion.

According to some implementations, the comparator and the analog-to-digital converter including the comparator may perform accurate analog-to-digital conversion even with low power consumption. While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A comparator comprising:
an input circuit configured to receive a first input signal and a second input signal;
a first sense amplifying circuit configured to amplify a potential difference between the first input signal and the second input signal and configured to generate a first output signal and a second output signal;
a first clocking transistor circuit configured to connect the input circuit to the first sense amplifying circuit based on a first clock signal;
a second sense amplifying circuit configured to amplify the potential difference between the first input signal and the second input signal and configured to generate a third output signal and a fourth output signal; and
a second clocking transistor circuit configured to connect the input circuit to the second sense amplifying circuit based on a second clock signal.

2. The comparator of claim 1, wherein first bit data is generated based on the first output signal and the second output signal, and second bit data is generated based on the third output signal and the fourth output signal.

3. The comparator of claim 1, wherein the first sense amplifying circuit and the second sense amplifying circuit each include a cross-coupled inverter.

4. The comparator of claim 3, wherein the first sense amplifying circuit includes a first CMOS circuit and a second CMOS circuit that are cross-coupled with each other, each of the first CMOS circuit and the second CMOS circuit including a PMOS pull-up transistor and an NMOS pull-down transistor, and
wherein the second sense amplifying circuit includes a third CMOS circuit and a fourth CMOS circuit that are cross-coupled with each other, each of the third CMOS circuit and the fourth CMOS circuit including a PMOS pull-up transistor and an NMOS pull-down transistor.

5. The comparator of claim 4, wherein the first clocking transistor circuit includes:
a first clocking transistor configured to connect a source node of the pull-down transistor of the first CMOS circuit to a drain node of a first input transistor configured to receive the first input signal, the first clocking transistor being configured to receive the first clock signal to a gate node; and
a second clocking transistor configured to connect a source node of the pull-down transistor of the second CMOS circuit to a drain node of a second input transistor configured to receive the second input signal, the second clocking transistor being configured to receive the first clock signal to a gate node, and
wherein the second clocking transistor circuit includes:
a third clocking transistor configured to connect a source node of the pull-down transistor of the third CMOS circuit to the drain node of the first input transistor configured to receive the first input signal, the third clocking transistor being configured to receive the second clock signal to a gate node; and
a fourth clocking transistor configured to connect a source node of the pull-down transistor of the fourth CMOS circuit to the drain node of the second input transistor configured to receive the second input signal, the fourth clocking transistor being configured to receive the second clock signal to a gate node, and
wherein the input circuit includes the first input transistor and the second input transistor.

6. The comparator of claim 1, further comprising:
a first node configured to connect the first sense amplifying circuit to the first clocking transistor circuit;
a second node configured to connect the second sense amplifying circuit to the second clocking transistor circuit;
a first pre-charge circuit configured to provide a power supply voltage to the first sense amplifying circuit and the first node based on the first clock signal; and
a second pre-charge circuit configured to provide the power supply voltage to the second sense amplifying circuit and the second node based on the second clock signal.

7. The comparator of claim 6,
wherein the first pre-charge circuit is configured to reset the first sense amplifying circuit and the first node based on the first clock signal being at a first level, and
wherein the second pre-charge circuit is configured to reset the second sense amplifying circuit and the second node based on the second clock signal being at the first level.

8. The comparator of claim 6, further comprising:
a first offset bias circuit including:
a first offset transistor connected to the first node and configured to receive the first clock signal to a gate node, and
a first bias transistor connected in series with the first offset transistor; and
a second offset bias circuit including:
a second offset transistor connected to the second node and configured to receive the second clock signal to a gate node, and
a second bias transistor connected in series with the second offset transistor.

9. The comparator of claim 1, wherein a phase of the first clock signal is different from a phase of the second clock signal.

10. The comparator of claim 9, wherein, based on one of the first clock signal and the second clock signal is at a second level, the other clock signal of the first clock signal and the second clock signal maintains a first level less than the second level.

11. The comparator of claim 10, wherein a period for maintaining the second level and a period for maintaining the first level of the first clock signal and the second clock signal are different from each other.

12. The comparator of claim 11, wherein the first clock signal is configured to transition from the second level to the first level, and the second clock signal is configured to, after a preset time, transition from the first level to the second level.

13. The comparator of claim 1, wherein the input circuit includes:
a first input transistor including:
a gate node configured to receive the first input signal,
a drain node connected to the first clocking transistor circuit and the second clocking transistor circuit, and
a source node connected to a ground node; and
a second input transistor including:
a gate node configured to receive the second input signal,
a drain node connected to the first clocking transistor circuit and the second clocking transistor circuit, and
a source node connected to the ground node.

14. The comparator of claim 1, wherein, based on the first clock signal being at a first level, the input circuit is connected to the first sense amplifying circuit through the first clocking transistor circuit,
wherein, based on the second clock signal being at the first level, the input circuit is connected to the second sense amplifying circuit through the second clocking transistor circuit, and
wherein the first clock signal and the second clock signal maintain the first level at different time intervals.

15. A comparator comprising:
an input circuit configured to receive a first input signal and a second input signal;
a plurality of sense amplifying circuits that are configured to amplify a potential difference between the first input signal and the second input signal and configured to generate output signals, based on a first clock signal and a second clock signal that alternately transition from a first level to a second level in different time intervals, respectively; and
a plurality of clocking transistor circuits configured to connect the input circuit to each of the plurality of sense amplifying circuits and to receive the first clock signal and the second clock signal.

16. The comparator of claim 15, wherein the input circuit is configured to connect each of the plurality of clocking transistor circuits to a ground node.

17. The comparator of claim 16,
wherein the plurality of sense amplifying circuits include a first sense amplifying circuit and a second sense amplifying circuit,
wherein the first sense amplifying circuit is configured to generate a first output signal and a second output signal based on the first input signal and the second input signal at the second level of the first clock signal, and
wherein the second sense amplifying circuit is configured to generate a third output signal and a fourth output signal based on the first input signal and the second input signal at the second level of the second clock signal.

18. An analog-to-digital converter comprising:
a digital-to-analog (DAC) circuit configured to generate a first input signal and a second input signal based on an input voltage;
a comparator configured to compare the input voltage with a reference voltage using the first input signal and the second input signal; and
a logic circuit configured to control the DAC circuit and to generate a digital output signal based on the comparison result of the comparator, and
wherein the comparator includes:
an input circuit configured to receive the first input signal and the second input signal;
a plurality of sense amplifying circuits configured to amplify a potential difference between the first input signal and the second input signal to generate output signals by, based on a first clock signal and a second clock signal that alternately transition from a first level to a second level in different time intervals, respectively; and
a plurality of clocking transistor circuits configured to connect the input circuit and each of the plurality of sense amplifying circuits and to receive the first clock signal and the second clock signal.

19. The analog-to-digital converter of claim 18, wherein the DAC circuit is a Capacitive Digital Analog Converter circuit.

20. The analog-to-digital converter of claim 19, wherein the input circuit is configured to connect each of the plurality of clocking transistor circuits to a ground node.
